(19) United States
(12) Patent Application Publication
(10) Pub. No.: US 2015/0185270 A1
(43) Pub. Date: Jul. 2, 2015

(54) Method for recognizing transformer partial discharge pattern based on singular value decomposition algorithm

(71) Applicant: STATE GRID CORPORATION OF CHINA, Beijing (CN)

(72) Inventors: Qijia Xie, Wuhan (CN); Chenghua Li, Wuhan (CN); Ling Ruan, Wuhan (CN); Jinbin Li, Wuhan (CN); Lei Su, Wuhan (CN); Ting Chen, Wuhan (CN); Xinfang Zhang, Wuhan (CN)

(21) Appl. No.: 14/416,637

(22) PCT Filed: Nov. 14, 2013
(86) PCT No.: PCT/CN2013/087100

§ 371 Date: Jan. 23, 2015

(30) Foreign Application Priority Data
Dec. 28, 2012 (CN) 201210581013.3

(51) Int. Cl. G01R 31/02; G01R 31/12; G06K 9/00

(52) U.S. Cl. CPC G01R 31/027; G06K 9/00536; G01R 31/1272

(57) ABSTRACT

A method for recognizing a transformer partial discharge pattern based on a singular value decomposition (SVD) algorithm includes a training model and a classification recognizing process, comprising: firstly setting up an experimental environment having artificial defects, collecting at least one datum sample, and calculating statistical feature parameters of each datum sample to form a datum sample matrix; performing singular value decomposition on the datum sample matrix and determining an order of an optimal retention matrix by judging whether a feature of a retention matrix is clear, so as to obtain a type feature description matrix and a class-center description vector group after dimensionality reduction; preprocessing samples to be recognized to obtain a sample vector, and performing linear transformation on the sample vector utilizing a type space description matrix.

### CROSS REFERENCE OF RELATED APPLICATION

This is a U.S. National Stage under 35 U.S.C. 371 of the International Application PCT/CN2013/087100, filed Nov. 14, 2013, which claims priority under 35 U.S.C. 119(a-d) to CN 201210581013.3, filed Dec. 28, 2012.

### BACKGROUND OF THE PRESENT INVENTION

1 . Field of Invention

The present invention relates to the field of power technology, and more particularly to a method for recognizing transformer partial discharge pattern based on singular value decomposition algorithm.

2 . Description of Related Arts

Partial discharge is one of the main causes of internal insulator deterioration of large transformers. On-line monitoring of partial discharge of a transformer is capable of timely and accurately judging internal insulation status of the transformers, and thus has great significance for preventing power transformer accidents. Two major problems in a partial discharge pattern recognizing method are selecting feature quantity and designing a classifier. In the conventional art, while selecting a statistical feature parameter for serving as a partial discharge feature, several statistical parameters are directly selected from a plurality of statistical parameters to serve as feature quantity, which mainly depends on practical experiences and lacks scientific basis. Or feature selecting method based on principal component analysis algorithm is adopted, but the method has a complicated process and is difficult to calculate.

Judging from structures of the classifier, in the conventional art, a classification method based on BP (Back Propagation) is mainly adopted. The method is sensitive in selecting an initial weight and a threshold value and easy to be caught in a local minimum point, which has disadvantages of causing a failure learning process, a slow convergence speed and a low efficiency.

### SUMMARY OF THE PRESENT INVENTION

In view of disadvantages in the conventional art, an objects of the present invention is to provide a method for recognizing a partial discharge pattern based on Singular Value Decomposition (SVD), so as to simplify processes of recognition and calculation, in such a manner that a recognizing method which has a high algorithm efficiency and a high classification recognizing efficiency and is capable of improving scientificity and accuracy of partial discharge diagnosis is obtained.

Accordingly, in order to accomplish the above objects, the present invention provides a method for recognizing a transformer partial discharge pattern based on a singular value decomposition algorithm, comprising following steps of:

step (1) setting up an experimental environment having multiple discharge patterns and artificial defects, and collecting at least one sample datum of partial discharge related measurement parameter;

step (2) calculating statistical feature parameters of the sample datum of related measurement parameter of partial discharge collected in the step (1);

step (3) forming a training sample matrix and a testing sample matrix, wherein composition structure of the training sample matrix and the testing sample matrix is the same, each row of the training sample matrix and the testing sample matrix is the statistical feature parameter, and each column thereof is a sample;

step (4) performing singular value decomposition on the training sample matrix and determining an optimal order of a retention matrix;

step (5) forming a classification model according to a sample matrix obtained by the singular value decomposition, wherein the classification model is formed by a type feature space description matrix and a class-center description vector group; and

step (6) preprocessing the testing sample matrix or on-site collected samples to be classified to obtain a sample vector to be classified, and performing classification recognizing.

Preferably, the experimental environment having artificial defects in the step (1) comprises:

a plurality of typical discharging types comprising surface discharge, internal discharge and bubble discharge; and

a plurality of interference types comprising air point discharge and corona discharge;

wherein each type of the sample datum of partial discharge related measurement parameter comprises: pulse discharging quantity, pulse phase, sampling frequency, amplitude range, triggering level, pulse number, measuring length, phase offset, measuring time, time interval, equivalent frequency and equivalent length.

Preferably, the statistical feature parameters in the step (2) are selected from the group consisting of:

repetitional discharge frequency, total discharge number, discharge duration time, positive polarity and negative polarity maximum discharge quantity, weighted average discharge phase of discharge number distribution of the positive polarity and the negative polarity, variance of the discharge number distribution of the positive polarity and the negative polarity, skewness of the discharge number distribution of the positive polarity and the negative polarity, steepness of the discharge number distribution of the positive polarity and the negative polarity, asymmetry of positive half period and negative half period of a discharge frequency distribution chart, correlation coefficient of positive half period and negative half period of the discharge frequency distribution chart;

variance of average discharge quantity distribution of the positive polarity and the negative polarity, skewness of the average discharge quantity distribution of the positive polarity and the negative polarity, steepness of the average discharge quantity distribution of the positive polarity and the negative polarity, asymmetry of positive half period and negative half period of the average discharge quantity distribution chart and correlation coefficient of positive half period and negative half period of the average discharge quantity distribution chart; and

alpha parameter of pulse amplitude Weibull distribution and beta parameter of pulse amplitude Weibull distribution.

Preferably, a specific method for forming the training sample matrix in the step (3) comprises steps of:

calculating statistical feature parameters of the sample datum of related measurement parameter of partial discharge to form column vectors of the training sample matrix;

continually adding the sample datum of each discharge pattern to columns of the training sample matrix, wherein each row of the training sample matrix represents one statistical feature parameter; and performing datum normalization calculation.

Preferably, a quantity ratio of training samples to testing examples of each discharge pattern is 2:1.

Preferably, the step (4) of determining an optimal order of a retention matrix specifically comprises:

obtaining the type feature space description matrix, a singular value matrix and a sample space description matrix by the singular value decomposition;

calculating a scattering matrix in one type, a scattering matrix between types and global matrix of all samples of the sample space description matrix, so as to obtain a characterization value for judging clustering degree; and

comparing the characterization value and the threshold value, and determining as the optimal order when the threshold value is less than threshold value.

Preferably, a specific process for the classification recognizing in the step (6) comprises steps of:

preprocessing the testing sample matrix or on-site collected samples to be classified to obtain the sample vector to be classified;

performing linear transformation on the type space description matrix obtained in the step (5), so as to obtain a sample description space vector after dimensionality reduction; and

then calculating degrees of similarity between the sample description space vector after dimensionality reduction and each vector in the class-center description vector group, wherein a most similar group serves a classification judgment result.

Preferably, the preprocessing comprises steps of: calculating the statistical feature parameters and performing normalization on the sample vector.

The present invention selects features having good distinctive capability in recognizing utilizing the singular value decomposition algorithm. The present invention has a simpler calculation than the principal component analysis algorithm and a high execution efficiency. For conventional statistical feature parameters, a result obtained by one-time screening is capable of being utilized repeatedly, and calculation at each time is not necessary. The method recited in the present invention overcomes problems brought by adopting a classification method based on a BP (Back Propagation) neural network algorithm. The present invention calculates category center point for calculating a distance between a sample and a category center. The calculation is simple and has a high efficiency.

Judging from the technical solutions mentioned above, compared with the conventional art, the present invention has beneficial effects as follows.

1. High calculation efficiency

Since the step (4) adopts performing singular value decomposition on the training sample matrix and obtains information of three types comprising the type feature space description matrix, the singular value matrix and the sample space description matrix by the singular value decomposition by a one-time decomposition algorithm, which is equivalent to accomplishing a function realized by a principal component analysis algorithm in two directions. The sample matrix is performed with dimensionality reduction by the singular value decomposition. Classification algorithm is performed in a dimensionality reduction space, and efficiency of the algorithm is improved.

2. High information utilization ratio

The method of the present invention fully utilizes physical significance represented by each matrix after the singular value decomposition. The step (4) utilizes the sample space description matrix to judge an optimal order of the retention matrix and the dimensionality reduction class-center description vector group, and further utilizes a retention singular value matrix and feature space description matrix to obtain the retention type feature space description matrix.

3. Simple implementation process of classification algorithm

In the step (5), the classification model is obtained by calculating the retention matrix performed by singular value decomposition. Compared with the conventional classification method of neural network algorithm, an additional constructing classifier is not needed.

4. High recognition rate

Since the method for judging orders of the retention matrix is not judged by contribution rate of singular value as utilized in the conventional method. A method for determining orders of an optimal retention matrix in the step (4) is capable of filtering unconcerned redundant information and simultaneously reflecting information of original datum as much as possible.

### BRIEF DESCRIPTION OF THE DRAWINGS

FIG. 1 is an overview flow chart according to a preferred embodiment of the present invention;

FIG. 2 is a schematic flow chart of an algorithm base on singular value decomposition;

FIG. 3 is a schematic view of a method for ensuring that an optimal order of a matrix is retained; and

FIG. 4 is a schematic view of a retention matrix after singular value decomposition.

### DETAILED DESCRIPTION OF THE PREFERRED EMBODIMENT

These and other objectives, features, and advantages of the present invention will become apparent from the following detailed description, and the accompanying drawings

One skilled in the art will understand that the embodiment of the present invention as shown in the drawings and described here is exemplary only and not intend to limit the scope of the invention.

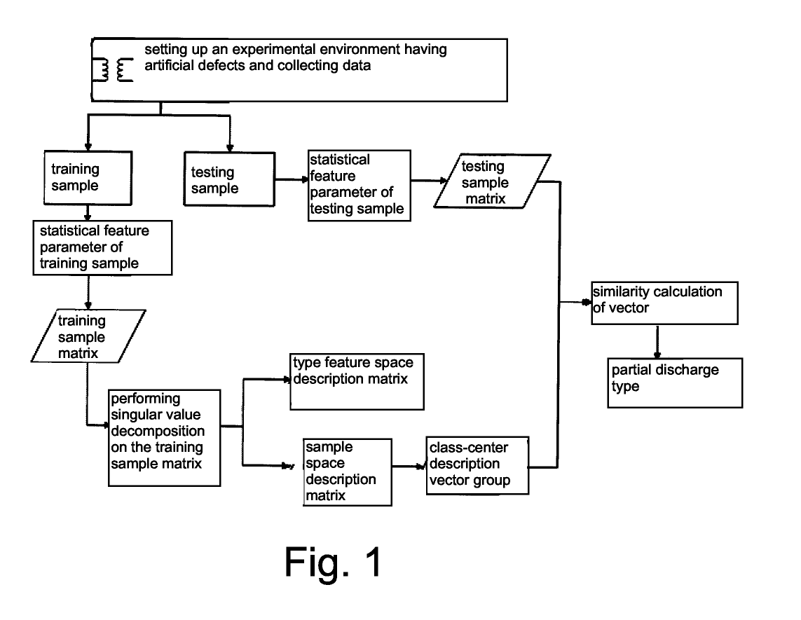

Referring to FIG. 1 of the drawings, according to a preferred embodiment of the present invention, the present invention provides a method for recognizing a transformer partial discharge pattern based on a singular value decomposition algorithm, comprising following steps (1)˜(6).

Step (1): setting up an experimental environment having artificial defects.

A plurality of typical discharging types comprising surface discharge, internal discharge and bubble discharge; and a plurality of interference types comprising air point discharge and corona discharge are specifically provided. An ultra-high frequency partial discharge detecting system is adopted to collect datum in a laboratory. Each type of the sample datum of partial discharge related measurement parameter comprises: pulse discharging quantity, pulse phase, sampling frequency, amplitude range, triggering level, pulse number, measuring length, phase offset, measuring time, time interval, equivalent frequency and equivalent length. Multiple sample data of the typical discharging types and the interference types are obtained, and two thirds of samples of each type are selected for training, and residual samples are for testing.

Step (2): calculating statistical feature parameters of each sample, wherein the statistical feature parameters comprise:

repetitional discharge frequency, total discharge number, discharge duration time, positive polarity and negative polarity maximum discharge quantity, weighted average discharge phase of discharge number distribution of the positive polarity and the negative polarity, variance of the discharge number distribution of the positive polarity and the negative polarity, skewness of the discharge number distribution of the positive polarity and the negative polarity, steepness of the discharge number distribution of the positive polarity and the negative polarity, asymmetry of positive half period and negative half period of a discharge frequency distribution chart, correlation coefficient of positive half period and negative half period of the discharge frequency distribution chart.

According to a preferred embodiment of the present invention, 25 parameters and 4 defect types are selected. Utilizing other parameters and defect types are not limited by the present invention.

Step (3): forming a partial discharge sample matrix A.

Specifically, statistical feature parameters of the sample datum of related measurement parameter of partial discharge are calculated and sorted out in groups according to types, so as to form a feature matrix as following expression, wherein each column of the feature matrix has one sample column vector. Each type of sample is continuously disposed in each column of the matrix, and each row represents a statistical feature parameter of one type.

According to another preferred embodiment of the present invention, a total number of 1×40=160 samples are selected for training in the step (1). In the step (2), 25 statistical feature parameters are calculated by each sample. 25 row vectors are in the following S matrix, and 160 sample column vectors in total are in samples of 4 types.

$$S = {[ \begin{matrix}{s}_{11} & {s}_{12} & … & {s}_{1 n} \\ {s}_{21} & {s}_{22} & … & {s}_{2 n} \\ ⋮ & ⋮ & ⋱ & ⋮ \\ {s}_{m 1} & {s}_{m 2} & … & {s}_{mn}\end{matrix} ] \begin{matrix}\begin{matrix}\begin{matrix}← feature 1 \\ ← feature 2\end{matrix} \\ …\end{matrix} \\ ← feature m\end{matrix} ,}^{\begin{matrix}sample & sample & & sample \\ & & … & \\ 1 & 2 & & n \\ ↓ & ↓ & & ↓\end{matrix}}$$

wherein n presents a number of the samples, and in the preferred embodiment n=160; m represents a number of features, and in the preferred embodiment m=25.

Performing datum normalization on the matrix S , so as to obtain a training sample matrix A. Specifically, normalization operation is performed on each statistical parameters by rows of the matrix S. Each element aᵢⱼ of the matrix A is calculated according to following expression:

$${a}_{ij} = \frac{\vert {s}_{ij} - {\overline{s}}_{i} \vert}{\sqrt{\frac{1}{n - 1} {\sum }_{j = 1}^{n} {( {s}_{ij} - {\overline{s}}_{i} )}^{2}}} ;$$

wherein s̅ᵢ an average value of each statistical feature parameter, and a calculating expression thereof is:

$${\overline{s}}_{i} = \frac{1}{n} {\sum }_{j = 1}^{n} {s}_{ij} .$$

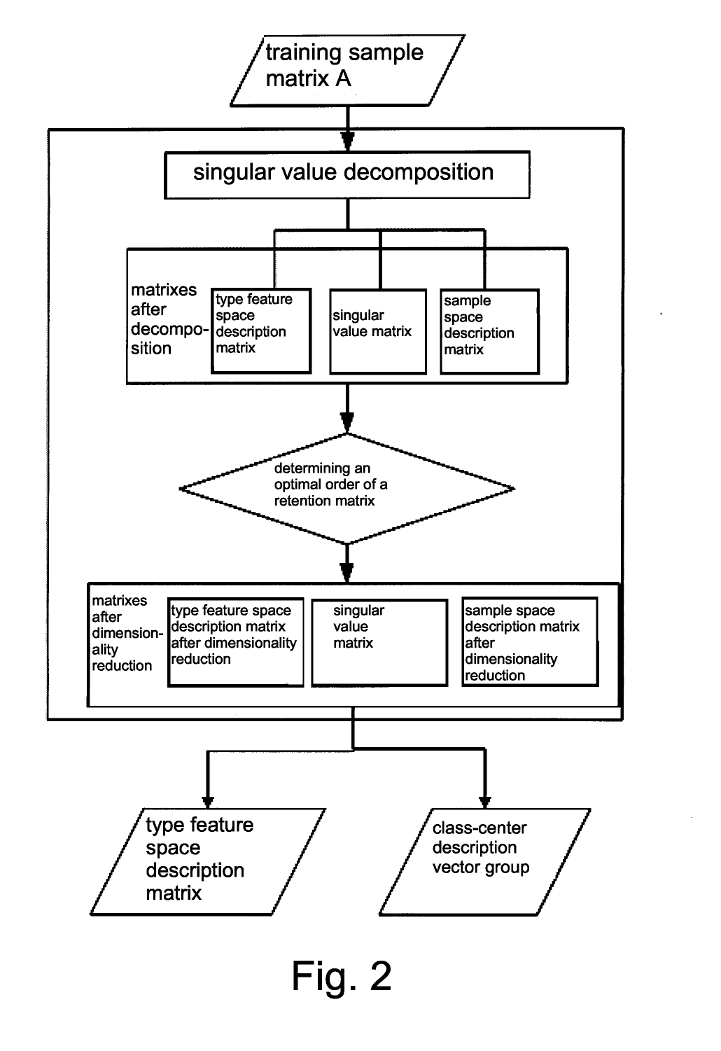

Step (4): performing singular value decomposition on the training sample matrix and determining an optimal order of a retention matrix (See FIG. 2 for a specific flow).

Specifically, singular value decomposition is performed on the matrix A formed in the step (3), wherein an output thereof is A=UΣV^{T},

wherein Σ is a singular value matrix and a diagonal matrix, wherein singular values are arranged from large to small order;

wherein feature space description matrix U reflects relationships among the statistical feature parameters, each row represents a parameter;

wherein a type feature space description matrix UΣ⁻¹ is used for forming a classification judgment matrix for a classification recognizing algorithm in a next step;

sample space description vector V^{T} reflects distance relationships among samples, each column thereof represents a sample; and

matrix V^{T} is for judging that whether target feature retained after dimensionality reduction is apparent.

A basic standard for judging that whether target feature retained is apparent is as follows. The smaller the distance among samples in one type in V^{T} the better; and the greater the distance among samples of different types the better.

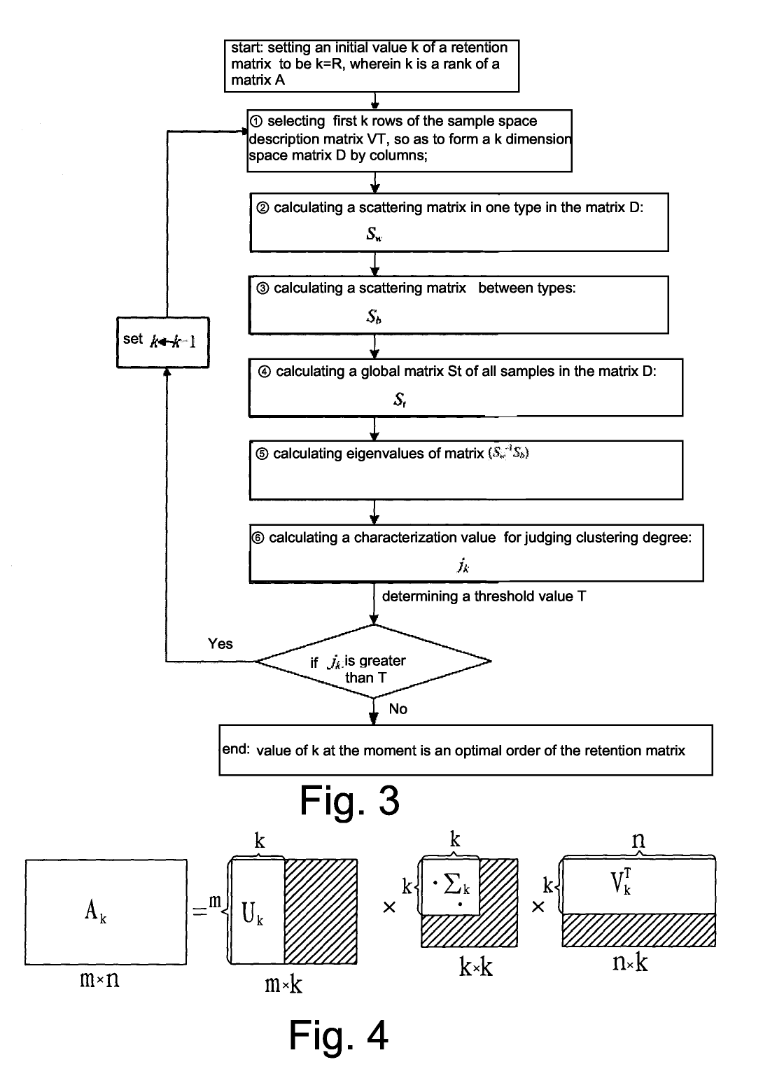

FIG. 3 shows a method for retaining an optimal order of the matrix. Specific illustration is as follows. A column vector set X of the matrix V^{T} comprises nⱼ samples which belong to c types. Each type forms a vector subset Xj (j=1, 2, . . . , c). Each subset has nⱼ samples. An initial value of a retention order k of the singular value matrix Σ is set as R, R is a rank of the matrix A, i.e., a number of nonzero singular values in the matrix Σ.

The method for retaining the optimal order of the matrix comprises steps of:

\textcircled{1} selecting first k rows of the sample space description matrix V^{T}, so as to form a k dimension space matrix D by columns;

\textcircled{2} calculating a scattering matrix S_{w} in one type in the matrix D, wherein a calculating expression is as follows:

$${S}_{w} = {\sum }_{j = 1}^{c} {P}_{j} \cdot {S}_{j} ;$$

wherein Pⱼ is a prior probability of each type, and a calculating expression is Pⱼ=nⱼ/n; Sⱼ is a scattering matrix in one type, and a calculating expression is as follows:

$${S}_{j} = \frac{1}{{n}_{j}} \sum ( {x}_{i}^{( j )} - {m}_{j} ) {( {x}_{i}^{( j )} - {m}_{j} )}^{T} ;$$

wherein xᵢ^{(j)} represents an ith sample vector of a vector subset Xⱼ, i=1, 2, 3, . . . , nⱼ, j=1, 2, 3, . . . , c; mⱼ is an average value vector of each type; ( )^{T} represents performing transposition operation on the matrix, which is similarly hereafter;

\textcircled{3} calculating a scattering matrix S_{b} between types, which is defined as:

$${S}_{b} = {\sum }_{j = 1}^{c} {P}_{j} \cdot ( {m}_{j} - m ) {( {m}_{j} - m )}^{T} ;$$

wherein meanings of Pⱼ and mⱼ are the same as mentioned above; m is an average value vector of all samples;

\textcircled{4} calculating a global matrix Sₜ of all samples in the matrix D, which is defined as follows:

Sₜ=S_{w}+S_{b};

\textcircled{5} calculating eigenvalues of matrix (S_{w}⁻¹S_{b});

\textcircled{6} calculating a characterization value Jₖ for judging clustering degree, which is defined as follows:

Jₖ=j₁+j₂+j₃+j₄;

wherein:

j₁=tᵣ(S_{w}⁻¹S_{b})

j₂=|S_{w}⁻¹S_{b}|

j₃=tᵣ(S_{w}⁻¹Sₜ)

j₄=|S_{w}⁻¹Sₜ|;

wherein k is a retention order, tᵣ represents a trace of the matrix, i.e., a sum of diagonal elements, and symbol “∥” represents a determinant;

\textcircled{7} determining a threshold value T, T=f×J_{R}; wherein J_{R} is a characterization value representing a clustering degree when the retention order k values a rank R of the matrix A;

f is a dimensionality reduction factor, 0<f<1, wherein a value off reflects requirements of users on the clustering degree; as a preferred embodiment, f=0.9, wherein values of Jₖ and T are compared; if Jₖ is greater than T, valuating k=k−1 to return back to the step \textcircled{1} if Jₖ is smaller than T, terminate and remain value of k at the moment;

in such a manner that three matrixes of Uₖ, Σₖ and Vₖ^{T} which have retention orders of k are obtained. Referring to FIG. 4, as a preferred embodiment, an optimal order of the retention matrix is selected as k=6.

Step (5) forming a classification model. Specifically, the retention matrixes Uₖ and Σₖ are calculated to obtain a dimensionality reduction type feature space description matrix A^{L}, and a calculating expression is as follows:

$${m}_{j} = \frac{1}{{n}_{j}} {\sum }_{i = 1}^{{n}_{j}} {x}_{i}^{( j )} ;$$

For the matrix Vₖ^{T}, a class-center description vector of each type is calculated, wherein mⱼ is obtained by calculating an average value of samples in a type j, and a calculating expression is as follows:

$${m}_{j} = \frac{1}{{n}_{j}} {\sum }_{i = 1}^{{n}_{j}} {x}_{i}^{( j )} ;$$

wherein xᵢ^{(j)} represents an ith sample vector of the vector subset Xⱼ, wherein i=1, 2, 3, . . . , nⱼ, j=1, 2, 3, . . . , c, c represents a total number of types.

Classification model description is formed by the type feature space description matrix A^{L} and the class-center description vector group.

Step (6) performing a classification recognizing process, which specifically comprises steps of:

\textcircled{1} preprocessing the testing sample matrix or on-site collected samples to be classified to obtain a sample vector y to be classified; which specifically comprises steps of: calculating the statistical feature parameter in the step (2) and performing normalization on the sample vector utilizing the method illustrated in the step (3);

\textcircled{2} performing linear transformation on the type space description matrix A^{L} obtained in the step (5), so as to obtain a sample description space vector y′ after dimensionality reduction, and a calculating expression is as follows

y′=y^{T}*A^{L};

\textcircled{3} calculating degrees of similarity between the vector y′ obtained in the step \textcircled{2} and each vector mⱼ in the sample description space vector set after dimensionality reduction in the step (5), so as to obtain a result of classification judgement, wherein specifically a cosine value of an included angle between the vector Y ′ and each vector mⱼ in the class-center description vector group, and a calculating expression is:

$$δ ( {y}^{′} , {m}_{j} ) = cos ( {y}^{′} , {m}_{j} ) = \frac{{m}_{j}^{T} \cdot {y}^{′}}{‖ {y}^{′} ‖ \cdot ‖ {m}_{j} ‖} ;$$

wherein ∥ ∥ represents a module of vectors calculated, and a total number of c cosine values are obtained, and a calculating result of the cosine values are sorted by size; wherein a type having an maximum value of δ is determined as a type of the sample vector y to be classified.

Those skilled in the art will readily appreciate that the above description is only preferred embodiments of the invention, not intended to limit the present invention. Any modification, equivalent replacement or improvement within the spirit and principles of the present invention without departing from the scope of the invention.

What is claimed is:

1. A method for recognizing a transformer partial discharge pattern based on a singular value decomposition algorithm, comprising following steps of:
step (1) setting up an experimental environment having multiple discharge patterns and artificial defects, and collecting at least one sample datum of partial discharge related measurement parameter;
step (2) calculating statistical feature parameters of the sample datum of related measurement parameter of partial discharge collected in the step (1);
step (3) forming a training sample matrix and a testing sample matrix, wherein composition structure of the training sample matrix and the testing sample matrix is the same, each row of the training sample matrix and the testing sample matrix is the statistical feature parameter, and each column thereof is a sample;
step (4) performing singular value decomposition on the training sample matrix and determining an optimal order of a retention matrix;
step (5) forming a classification model according to a sample matrix obtained by the singular value decomposition, wherein the classification model is formed by a type feature space description matrix and a class-center description vector group; and
step (6) preprocessing the testing sample matrix or on-site collected samples to be classified to obtain a sample vector to be classified, and performing classification recognizing.

2. The method for recognizing the transformer partial discharge pattern based on the singular value decomposition algorithm, as recited in claim 1, wherein the experimental environment having artificial defects in the step (1) comprises:
a plurality of typical discharging types comprising surface discharge, internal discharge and bubble discharge; and
a plurality of interference types comprising air point discharge and corona discharge;
wherein each type of the sample datum of partial discharge related measurement parameter comprises: pulse discharging quantity, pulse phase, sampling frequency, amplitude range, triggering level, pulse number, measuring length, phase offset, measuring time, time interval, equivalent frequency and equivalent length.

3. The method for recognizing the transformer partial discharge pattern based on the singular value decomposition algorithm, as recited in claim 1, wherein the statistical feature parameters in the step (2) are selected from the group consisting of:
repetitional discharge frequency, total discharge number, discharge duration time, positive polarity and negative polarity maximum discharge quantity, weighted average discharge phase of discharge number distribution of the positive polarity and the negative polarity, variance of the discharge number distribution of the positive polarity and the negative polarity, skewness of the discharge number distribution of the positive polarity and the negative polarity, steepness of the discharge number distribution of the positive polarity and the negative polarity, asymmetry of positive half period and negative half period of a discharge frequency distribution chart, correlation coefficient of positive half period and negative half period of the discharge frequency distribution chart;
variance of average discharge quantity distribution of the positive polarity and the negative polarity, skewness of the average discharge quantity distribution of the positive polarity and the negative polarity, steepness of the average discharge quantity distribution of the positive polarity and the negative polarity, asymmetry of positive half period and negative half period of the average discharge quantity distribution chart, correlation coefficient of positive half period and negative half period of the average discharge quantity distribution chart; and
alpha parameter of pulse amplitude Weibull distribution and beta parameter of pulse amplitude Weibull distribution.

4. The method for recognizing the transformer partial discharge pattern based on the singular value decomposition algorithm, as recited in claim 1, wherein a specific method for forming the training sample matrix in the step (3) comprises steps of:
calculating statistical feature parameters of the sample datum of related measurement parameter of partial discharge to form column vectors of the training sample matrix;
continually adding the sample datum of each discharge pattern to columns of the training sample matrix, wherein each row of the training sample matrix represents one statistical feature parameter; and
performing datum normalization calculation.

5. The method for recognizing the transformer partial discharge pattern based on the singular value decomposition algorithm, as recited in claim 1, wherein a quantity ratio of training samples to testing examples of each discharge pattern is 2:1.

6. The method for recognizing a transformer partial discharge pattern based on the singular value decomposition algorithm, as recited in claim 1, wherein the step (4) of determining an optimal order of a retention matrix specifically comprises:
obtaining the type feature space description matrix, a singular value matrix and a sample space description matrix by the singular value decomposition;
calculating a scattering matrix in one type, a scattering matrix between types and global matrix of all samples of the sample space description matrix, so as to obtain a characterization value for judging clustering degree; and
comparing the characterization value and the threshold value, and determining as the optimal order when the threshold value is less than a threshold value.

7. The method for recognizing a transformer partial discharge pattern based on the singular value decomposition algorithm, as recited in claim 1, wherein a specific process for the classification recognizing in the step (6) comprises steps of:
preprocessing the testing sample matrix or on-site collected samples to be classified to obtain the sample vector to be classified;
performing linear transformation on the type space description matrix obtained in the step (5), so as to obtain a sample description space vector after dimensionality reduction; and
then calculating degrees of similarity between the sample description space vector after dimensionality reduction and each vector in the class-center description vector group, wherein a most similar group serves a classification judgment result.

8. The method for recognizing a transformer partial discharge pattern based on the singular value decomposition algorithm, as recited in claim 7, wherein the preprocessing comprises steps of: calculating the statistical feature parameters and performing normalization on the sample vector.
